(19) United States
(12) Patent Application Publication
(10) Pub. No.: US 2023/0020459 A1
(43) Pub. Date: Jan. 19, 2023

(54) ELECTRO-STATIC DISCHARGE PROTECTION CIRCUIT AND SEMICONDUCTOR DEVICE

(71) Applicant: CHANGXIN MEMORY TECHNOLOGIES, INC., Hefei City (CN)

(72) Inventor: Qian XU, Hefei (CN)

(21) Appl. No.: 17/860,415

(22) Filed: Jul. 8, 2022

Related U.S. Application Data
(63) Continuation of application No. PCT/CN2021/128098, filed on Nov. 2, 2021.

(30) Foreign Application Priority Data
Jul. 16, 2021 (CN) 202110806980.4

(51) Int. Cl. H01L 27/02

(52) U.S. Cl. CPC H01L 27/0262

(57) ABSTRACT

An electro-static discharge protection circuit and a semiconductor device are provided. The electro-static discharge protection circuit includes: an electro-static discharge path including a Silicon Controlled Rectifier (SCR) connected between a first potential terminal and a second potential terminal; a Negative channel-Metal-Oxide-Semiconductor (NMOS) transistor connected to the SCR and configured to be turned on by an electro-static voltage, to trigger the SCR to be turned on; and a first resistance connected in parallel with at least part of the electro-static discharge path and configured to shunt a current of the electro-static discharge path when the SCR is turned on.

### CROSS-REFERENCE TO RELATED APPLICATIONS

This is a continuation application of International Patent Application No. PCT/CN2021/128098, filed on Nov. 2, 2021, which claims priority to Chinese patent application No. 202110806980.4, filed on Jul. 16, 2021 and entitled “ELECTRO-STATIC DISCHARGE PROTECTION CIRCUIT AND SEMICONDUCTOR DEVICE”. The disclosures of International Patent Application No. PCT/CN2021/128098 and Chinese patent application No. 202110806980.4 are hereby incorporated by reference in their entireties.

### BACKGROUND

For a semiconductor device, static electricity is an unavoidable problem. In order to reduce an influence of the static electricity on the semiconductor device, it is necessary to design an effective Electro-Static Discharge (ESD) protection circuit during manufacturing of the semiconductor device. However, with the continuous development of large-scale integrated circuits, demand for high integration is continuously increased. As the device becomes more precise, the design of the ESD protection circuit faces a great challenge.

### SUMMARY

Embodiments of the disclosure relate to technology of semiconductor manufacturing, and in particular but not limited to an ESD protection circuit and a semiconductor device.

The ESD protection circuit includes an electro-static discharge path, a Negative channel-Metal-Oxide-Semiconductor (NMOS) transistor and a first resistance.

The electro-static discharge path includes a Silicon Controlled Rectifier (SCR) connected between a first potential terminal and a second potential terminal.

The NMOS transistor is connected to the SCR and configured to be turned on by an electro-static voltage, to trigger the SCR to be turned on.

The first resistance is connected in parallel with at least part of the electro-static discharge path and configured to shunt a current of the electro-static discharge path when the SCR is turned on.

Embodiments of the present disclosure further provide a semiconductor device. The semiconductor device includes a substrate, an N-well, a P-well and a first resistance.

The N-well and the P-well are arranged adjacently on the substrate.

An upper surface layer of the N-well includes a first ion implantation region, and the first ion implantation region is connected to a first potential terminal.

An upper surface layer of the P-well includes a second ion implantation region, and the second ion implantation region is connected to a second potential terminal.

The first ion implantation region and the second ion implantation region are configured to form an electro-static discharge path with the N-well and the P-well.

The upper surface layer of the P-well further includes an NMOS transistor connected to the electro-static discharge path. The NMOS transistor is configured to be turned on by an electro-static voltage, to turn on the electro-static discharge path by the electro-static voltage.

The first resistance is connected between the electro-static discharge path and the second potential terminal.

### BRIEF DESCRIPTION OF THE DRAWINGS

FIG. 1 is a first schematic diagram of a structure of an ESD protection circuit according to an embodiment of the present disclosure.

FIG. 2 is a second schematic diagram of a structure of an ESD protection circuit according to an embodiment of the present disclosure.

FIG. 3 is a third schematic diagram of a structure of an ESD protection circuit according to an embodiment of the present disclosure.

FIG. 4 is a fourth schematic diagram of a structure of an ESD protection circuit according to an embodiment of the present disclosure.

FIG. 5 is a first schematic diagram of a structure of a semiconductor device according to an embodiment of the present disclosure.

FIG. 6 is a second schematic diagram of a structure of a semiconductor device according to an embodiment of the present disclosure.

FIG. 7 is a third schematic diagram of a structure of a semiconductor device according to an embodiment of the present disclosure.

FIG. 8 is a schematic diagram of an ESD protection circuit according to an embodiment of the present disclosure.

FIG. 9 is a schematic diagram of a current-voltage (IV) characteristic curve of an SCR ESD protection circuit according to an embodiment of the present disclosure.

FIG. 10 is a schematic diagram of a design window of an ESD protection circuit according to an embodiment of the present disclosure.

FIG. 11 is a schematic diagram of a Low Voltage Trigger SCR (LVTSCR) ESD protection circuit according to an embodiment of the present disclosure.

FIG. 12 is a schematic diagram of a structure of an ESD protection circuit according to an embodiment of the present disclosure.

FIG. 13 is a layout of an ESD protection circuit according to an embodiment of the present disclosure.

### DETAILED DESCRIPTION

Generally, during manufacturing of semiconductor integrated circuits, ESD protection circuits are used for protecting positions where static electricity is likely to occur, such as a pad. These protection circuits may quickly discharge electro-static charges when ESD is generated at the pads, to protect the integrated circuit product and reduce electro-static damage. Embodiments of the disclosure provide an ESD protection circuit, which may be applied to a precise integrated circuit structure. The ESD protection circuit can facilitate rapid discharge of the electro-static charges, protect the integrated circuit product, and prolong a service life of the product.

The technical solution of the present disclosure will be further described in detail below with reference to the drawings and embodiments.

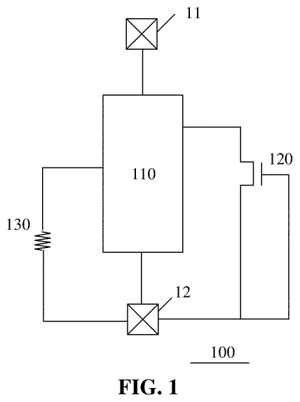

An embodiment of the disclosure provides an ESD protection circuit, as illustrated in FIG. 1. The ESD protection circuit 100 includes an electro-static discharge path 110, an NMOS transistor 120 and a first resistance 130.

The electro-static discharge path 110 includes an SCR connected between a first potential terminal 11 and a second potential terminal 12.

The NMOS transistor 120 is connected to the SCR and configured to be turned on by an electro-static voltage, to trigger the SCR to be turned on.

The first resistance 130 is connected in parallel with at least part of the electro-static discharge path 110 and configured to shunt a current of the electro-static discharge path 110 when the SCR is turned on.

The first potential terminal and the second potential terminal may be pads where the ESD is likely to occur or may be terminals connected to the pads, and may be connected to an external circuit, connected to a fixed voltage terminal, or grounded. For example, the first potential terminal may be an anode of the circuit and connected to a positive potential. The second potential terminal may be a cathode of the circuit and connected to a negative potential or grounded.

The electro-static discharge path includes an SCR. The SCR may be formed by a discharge device composed of a bipolar transistor, a trigger device triggering the discharge device to be turned on, and the like. The SCR may be formed in a substrate diffusion region and a well region of a semiconductor device, and an NPN structure or a PNP structure formed between different substrate diffusion regions and wells may form the bipolar transistor.

The application of the SCR in the electro-static discharge path may facilitate a circuit integrated in a semiconductor product, and is suitable for large-scale integrated circuits with high integration. However, the SCR is prone to latch-up. When the SCR is triggered to be turned on by the static electricity, the first potential terminal and the second potential terminal are in a low resistance state, which results in continuous current leakage and causing the device to burn out.

Therefore, in the embodiment of the disclosure, the SCR is triggered by the NMOS to form an electro-static discharge path and then to form an LVTSCR. In addition, in the embodiment of the disclosure, the first resistance is connected in parallel with at least part of the electro-static discharge path, so that a current of the electro-static discharge path is shunted when the SCR is turned on. Therefore, a large current is required when the SCR is turned on, and the capability of latch-up immunity of the ESD protection circuit can be improved, thereby improving product performance and reducing electro-static damage.

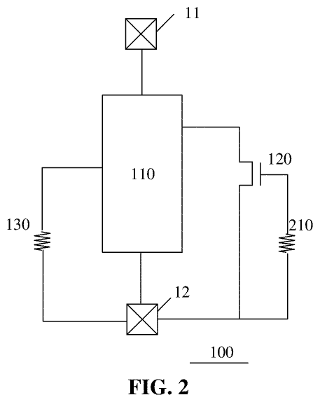

In some embodiments, as illustrated in FIG. 2, the ESD protection circuit further includes a second resistance 210.

The second resistance 210 is connected between a gate of the NMOS transistor 120 and the second potential terminal 12.

In such way, when electro-static charges are generated at the second potential terminal, the NMOS transistor may be triggered to be turned on by the second resistance, such that the SCR is triggered to be turned on, to turn on the electro-static discharge path.

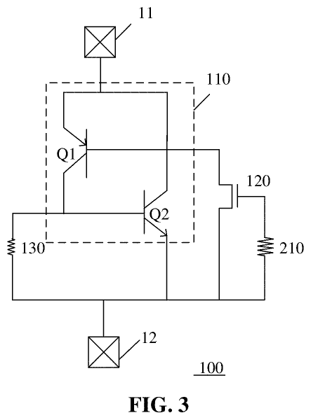

In some embodiments, as illustrated in FIG. 3, the SCR includes a PNP-type transistor Q1 and an NPN-type transistor Q2.

In the embodiment of the disclosure, the SCR consists of two switches, i.e., Q1 and Q2 as described above. Both the PNP-type transistor Q1 and the NPN-type transistor Q2 are three-terminal devices with a control terminal, and Q1 and Q2 are connected to each other to control each other and to form a discharge path.

In some embodiments, an emitter of the PNP-type transistor Q1 is connected to the first potential terminal 11.

A collector of the PNP-type transistor Q1 is connected to a base of the NPN-type transistor Q2.

A base of the PNP-type transistor Q1 is connected to a collector of the NPN-type transistor Q2.

An emitter of the NPN-type transistor Q2 is connected to the second potential terminal 12.

The PNP-type transistor is formed by an N-type semiconductor sandwiched between two P-type semiconductors. The P-type transistor includes the emitter and the collector at both ends, and the control terminal (also called the base).

When the PNP-type transistor is turned on, a current flows into the transistor at the emitter and flows out from the collector.

The above-mentioned NPN-type transistor is formed by a P-type semiconductor sandwiched between two N-type semiconductors. The NPN-type transistor includes the emitter and the collector at both ends, and the control terminal (also called the base).

When the NPN-type transistor is turned on, a current flows into the transistor at the collector and flows out from the emitter.

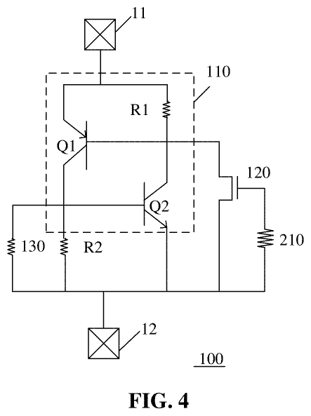

In some embodiments, as illustrated in FIG. 4, the electro-static discharge path further includes a first parasitic resistance R1.

The first parasitic resistance R1 is located between the emitter of the PNP-type transistor Q1 and the base of the PNP-type transistor Q1.

In the embodiment of the disclosure, the emitter of Q1 is connected to the first potential terminal, and the base (i.e., the control terminal) is connected to the first potential terminal through the first parasitic resistance R1. Therefore, when the static electricity is generated, a voltage at the emitter of Q1 is greater than a voltage at the base of Q1, which enables the Q1 to be turned on.

The collector of Q2 is connected to the first potential terminal through the first parasitic resistance, and the emitter of Q2 is connected to the second potential terminal. When Q2 is turned on, the electro-static charges may be discharged through the second switch.

In some embodiments, the first parasitic resistance is configured to form an N-well in a semiconductor device in which the ESD protection circuit is formed.

Since the ESD protection circuit may be formed in a semiconductor device, regions such as a P-well and an N-well may be formed by doping and other processes on a surface of the semiconductor device, and the regions are used to form the above-mentioned PNP-type transistor and NPN-type transistor with a substrate. Therefore, the first parasitic resistance may be a resistance of the N-well in the PNP-type transistor, and the whole ESD protection circuit may be formed by utilizing the structural characteristics of the semiconductor device itself without an external resistance.

In some embodiments, as illustrated in FIG. 4, the electro-static discharge path further includes a second parasitic resistance R2 located between the emitter of the NPN-type transistor Q2 and the base of the NPN-type transistor Q2.

In the embodiment of the disclosure, the emitter of Q2 is connected to the second potential terminal, and the base of Q2 is connected to the emitter of Q2 and the second potential terminal through the second parasitic resistance. Therefore, when the static electricity is generated, a voltage at the emitter of Q2 is less than a voltage at the base of Q2, which enables the Q2 to be turned on. Therefore, the charges are discharged.

In some embodiments, the second parasitic resistance is configured to form a P-well in the semiconductor device in which the ESD protection circuit is formed.

Similar to the first parasitic resistance, the second parasitic resistance may be a resistance of the P-well in the NPN-type transistor.

In some embodiments, the first resistance is connected between the emitter of the NPN-type transistor Q2 and the base of the NPN-type transistor Q2, and the first resistance 130 is connected in parallel with the second parasitic resistance R2.

If the resistance of the P-well is large, the SCR is prone to latch-up when being influenced by a large current. Therefore, the first resistance is connected in parallel to shunt the current, so as to reduce the current flowing through the base of Q2, and to reduce the probability of latch-up.

According to the ESD protection circuit provided by the technical solution in the embodiments of the present disclosure, the SCR may be triggered by the NMOS, so that a trigger voltage of the electro-static discharge path is low and a holding voltage of the electro-static discharge path is high. Moreover, the first resistance is connected in parallel with at least part of the electro-static discharge path and configured to shunt a current of the electro-static discharge path, so that the capability of latch-up immunity of the ESD protection circuit can be improved, and performance of the product can be improved.

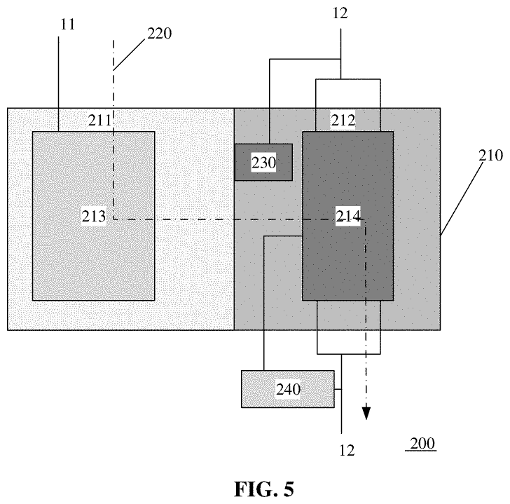

Embodiments of the disclosure further provide a semiconductor device. As illustrated in FIG. 5, the semiconductor device 200 includes a substrate 210, an N-well 211, a P-well 212 and a first resistance 240.

The N-well 211 and the P-well 212 are arranged adjacently on the substrate 210.

An upper surface layer of the N-well 211 includes a first ion implantation region 213, and the first ion implantation region 213 is connected to a first potential terminal 11.

An upper surface layer of the P-well 212 includes a second ion implantation region 214, and the second ion implantation region 214 is connected to a second potential terminal 12.

The first ion implantation region 213 and the second ion implantation region 214 are configured to form an electro-static discharge path 220 with the N-well 211 and the P-well 212.

The upper surface layer of the P-well 212 further includes an NMOS transistor 230 connected to the electro-static discharge path. The NMOS transistor is configured to be turned on by an electro-static voltage, to turn on the electro-static discharge path 220 by the electro-static voltage.

The first resistance 240 is connected between the electro-static discharge path 220 and the second potential terminal 12.

The semiconductor device in the embodiments of the present disclosure may include a memory, a processor and other various types of large-scale integrated circuits manufactured by using a semiconductor manufacturing process.

During the manufacturing of the semiconductor device, well regions, including an N-well and a P-well, may be formed by ion diffusion or lightly doping on the substrate. Then, ion implantation is performed on each of the upper surface layers of the N-well and the P-well, to form heavily doped ion implantation regions. The first ion implantation region and the second ion implantation region may include an N-type ion implantation region and a P-type ion implantation region, respectively, to form the NPN-type transistor structure and the PNP-type transistor structure.

In addition, the upper surface layer of the P-well may also be used for manufacturing the NMOS transistor. For example, a source and a drain of the NMOS transistor are formed by the ion implantation region, and the surface layer is further covered with a gate oxide layer and a gate conductive layer such as polysilicon, to form a gate of the NMOS transistor.

During the manufacturing of the semiconductor device, the ESD protection circuit is formed by using a semiconductor material, thereby protecting the semiconductor device and reducing the influence of static electricity on the semiconductor device.

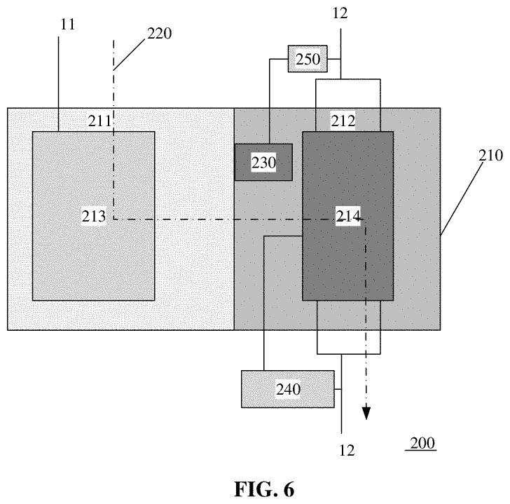

In some embodiments, as illustrated in FIG. 6, the semiconductor device 200 further includes a second resistance 250.

The second resistance 250 is connected between a gate of the NMOS transistor 230 and the second potential terminal 12.

In the embodiment of the disclosure, in the ESD protection circuit, the second resistance may be connected between the gate of the NMOS transistor and the second potential terminal. In such way, when electro-static charges are generated at the second potential terminal, the NMOS transistor may be triggered to be turned on through the second resistance, and then the SCR is triggered to be turned on, to turn on the electro-static discharge path.

The second resistance may be an external resistance connected to an external substrate through a wire during the manufacturing of the semiconductor device, and may also be a resistance formed by the substrate and materials in other device structures. For example, the second resistance may be a resistance of the P-well itself.

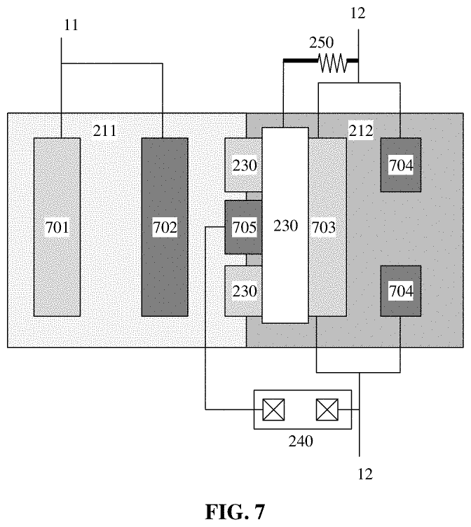

In some embodiments, as illustrated in FIG. 7, the first ion implantation region 213 includes a first N-type implantation region 701 (N+) and a first P-type implantation region 702 (P+), and both the first N-type implantation region and the first P-type implantation region are connected to the first potential terminal 11.

In some embodiments, the second ion implantation region includes a second N-type implantation region 703 (N+) and a second P-type implantation region 704 (P+), and both the second N-type implantation region and the second P-type implantation region are connected to the second potential terminal 12.

The first P-type implantation region, the N-well, the first N-type implantation region and the second P-type implantation region are configured to form a PNP-type transistor of the electro-static discharge path.

The first N-type implantation region, the N-well, the P-well and the second N-type implantation region are configured to form an NPN-type transistor of the electro-static discharge path.

As an example, in the structure illustrated in FIG. 7, the first P-type implantation region 702, the N-well 211 and the second P-type implantation region 704 may form a PNP-type transistor. An emitter of the PNP-type transistor, i.e., the first P-type implantation region 702, is connected to the first potential terminal 11, an collector of the PNP-type transistor, i.e., the second P-type implantation region 704, is connected to the second potential terminal 12 through the resistance of the P-well.

The first N-type implantation region 701, the N-well 211, the second P-type implantation region 704 and the second N-type implantation region 703 form an NPN-type transistor. A collector of the NPN-type transistor, i.e., the first N-type implantation region, is connected to the first potential terminal 11 through a resistance of the N-well, an emitter of the NPN-type transistor, i.e., the second N-type implantation region 703, is connected to the second potential terminal 12, and a base of the NPN-type transistor, i.e., the second P-type implantation region 704, is connected to the second potential terminal through the resistance of the P-well. The second P-type implantation region 704 also serves as a collector of the PNP-type transistor.

In some embodiments, the N-well includes a first parasitic resistance, and the P-well includes a second parasitic resistance.

The first parasitic resistance and the second parasitic resistance are internal resistances of the N-well and P-well, respectively. When a well region and other ion implantation regions form a transistor, the internal resistance of the N-well may divide voltage when a current passes through the N-well, and thus the internal resistance of the N-well may be equivalent to the external resistance of the transistor.

In some embodiments, the semiconductor device further includes a third P-type implantation region located in a surface layer of an interface between the N-well and the P-well.

The first resistance is connected between the third P-type implantation region and the second potential terminal.

As illustrated in FIG. 7, herein, the first resistance 240 may be connected to the second potential terminal through a wire connected to the third P-type implantation region 705. The first resistance may be implemented by a resistor, or may be implemented by a thin film with a conductive property, for example, a polysilicon thin film.

The embodiments of the disclosure further provide the following examples.

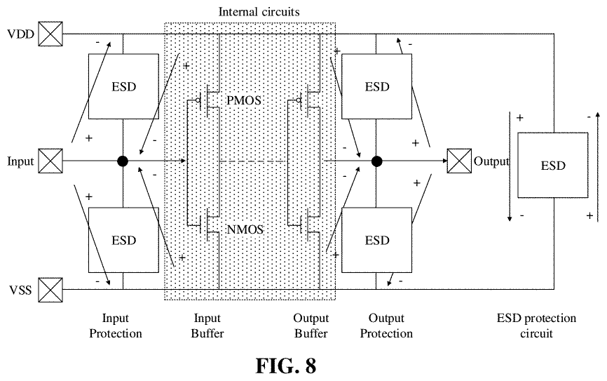

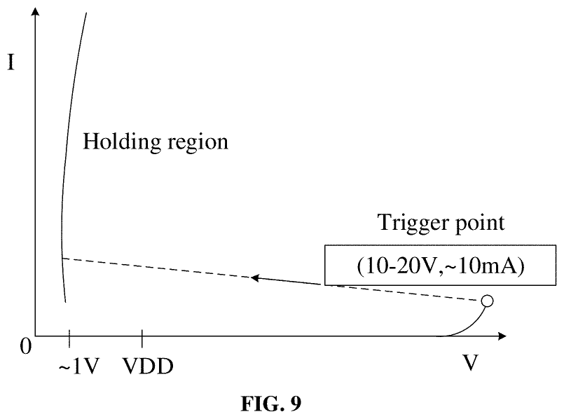

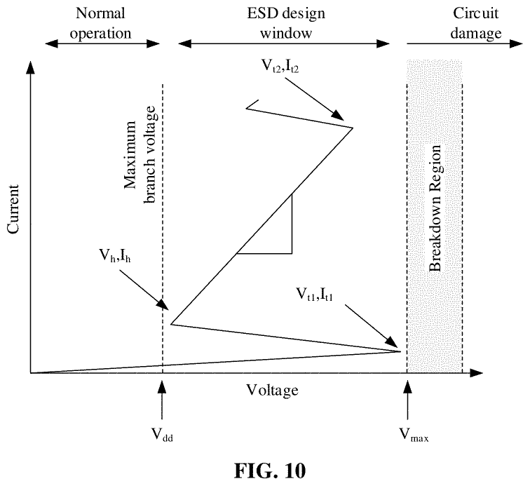

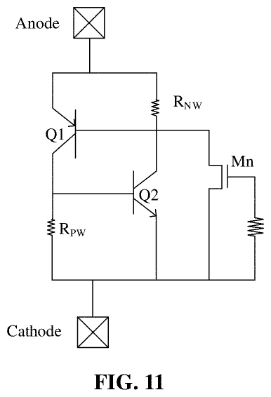

As the manufacturing process of modern semiconductors is becoming more advanced, a channel length is getting shorter, and a junction depth is getting shallower. In applications of silicide and Lightly Doped Drain (LDD), an oxide layer is getting thinner, a design window of the ESD is getting smaller, and challenges of the ESD protection design are getting bigger. In order to protect the integrated circuit and reduce the harm caused by the static electricity, the integrated circuit is generally required to be protected from static electricity. FIG. 8 is a schematic diagram of an ESD protection circuit. The ESD devices used herein may include diodes, MOSs and SCRs, etc. However, the conventional SCR has a high trigger voltage and a low holding voltage, and is prone to latch-up, which is not suitable for ESD protection for DRAM products. FIG. 9 illustrates an IV curve of the SCR. The IV curve deviates from the design window of the ESD, as illustrated in FIG. 10. In order to apply the SCR in the ESD protection of the DRAM products, the LVTSCR illustrated in FIG. 11 provides an ESD protection circuit with good performance. In the FIG. 11, Q1 and Q2 form the SCR, which is controlled and triggered by the NMOS, that is, Mn in the figure, and R_{N}w is a substrate resistance. However, this SCR structure is prone to latch-up.

The ESD protection circuit provided by the embodiments of the present disclosure has a characteristic of a large conduction current of the SCR, thereby improving the capability of latch-up immunity of the LVTSCR.

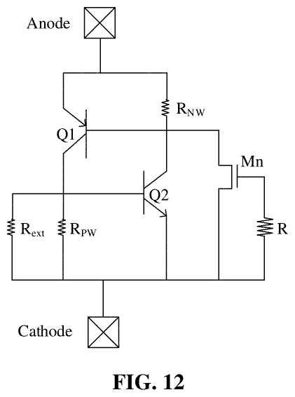

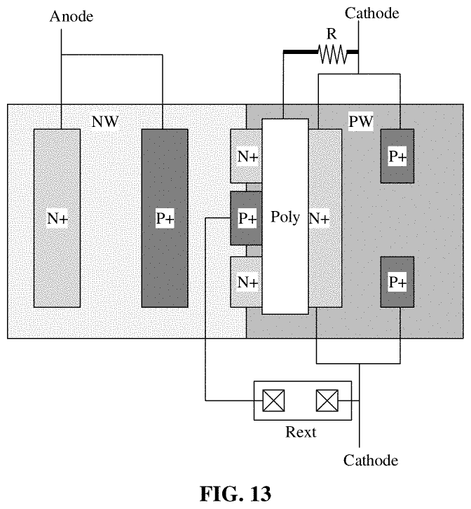

The ESD protection circuit provided by the embodiments of the present disclosure is illustrated in FIG. 12. When static electricity is generated, the transistor Mn is turned on, and the SCR consisting of Q1 and Q2 is triggered to be turned on to discharge the electro-static current. The layout of the improved LVTSCR ESD protection circuit is illustrated in FIG. 13. In the improved layout, the first resistance Rext and the second parasitic resistance Rpw are connected in parallel. Rext may be implemented by a poly resistance, and Rext has a small resistance and is adjustable. The total resistance of Rext and Rpw connected in parallel is relatively small, and the diode of Q2 requires a relatively large current to be turned on. Therefore, the capability of latch-up immunity of the LVTSCR can be improved.

It is to be understood that reference throughout the description to “one embodiment” or “an embodiment” refers to a particular feature, structure or characteristic associated with the embodiment being included in at least one embodiment of the present disclosure. Thus, the expression “in one embodiment” or “in an embodiment” in various places throughout this specification are not necessarily referring to the same embodiment. Furthermore, the particular feature, structure or characteristic may be combined in one or more embodiments in any suitable manner. It should be understood that in various embodiments of the disclosure, the serial number of the process does not represent an execution order, and the execution order of each process are determined by its function and inherent logic, and is not intended to limit the implementation process of the embodiments of the disclosure in any way. The above-mentioned serial numbers of the embodiments of the present disclosure are only for description, and do not represent the preferences of the embodiments.

It is to be understood that, terms like “including”, “comprising” or any other variant thereof are intended to cover non-exclusive inclusions. Therefore, a process, method, product or device that includes a series of elements not only includes such elements, but also includes other elements not specified expressly, or may include inherent elements of the process, method, product or device. Unless otherwise specified, an element modified by “including a/an . . . ” does not exclude other same elements existing in the process, method, product or device that includes the element.

In some embodiments provided by the disclosure, it is to be understood that the disclosed device and method may be implemented in another manner The device embodiment described above is only schematic, and for example, division of the units is only logic function division, and other division manners may be adopted during practical implementation. For example, multiple units or components may be combined or integrated into another system, or some characteristics may be neglected or not executed. In addition, coupling or direct coupling or communication connection between each displayed or discussed component may be indirect coupling or communication connection implemented through some interfaces, device or units, and may be electrical, mechanical or adopt other forms.

The units described as separate parts may or may not be physically separated, and parts displayed as units may or may not be physical units, and namely may be located in the same place, or may also be distributed to multiple network units. Part of all of the units may be selected according to a practical requirement to achieve the purposes of the solutions in the embodiments.

In addition, each functional unit in each embodiment of the disclosure may be integrated into a processing unit, each unit may also serve as an independent unit and two or more than two units may also be integrated into a unit. The integrated unit may be implemented in a hardware form and may also be implemented in form of hardware and software functional unit.

Described above are merely specific embodiments of the disclosure and not intended to limit the scope of protection of the disclosure. Any variations or replacements apparent to those skilled in the art within the technical scope disclosed by the disclosure shall fall within the scope of protection of the disclosure. Therefore, the scope of protection of the disclosure shall be subject to the scope of protection of the claims.

### INDUSTRIAL APPLICABILITY

According to the ESD protection circuit provided by the technical solution in the embodiments of the present disclosure, the SCR may be triggered by the NMOS transistor, so that a trigger voltage of the electro-static discharge path is low and a holding voltage is high. Moreover, the first resistance is connected in parallel with at least part of the electro-static discharge path to shunt a current of the electro-static discharge path, the capability of latch-up immunity of the ESD protection circuit can be improved, and product performance can be improved.

1. An Electro-Static Discharge (ESD) protection circuit, comprising:
an electro-static discharge path, comprising a Silicon Controlled Rectifier (SCR) connected between a first potential terminal and a second potential terminal;
a Negative channel-Metal-Oxide-Semiconductor (NMOS) transistor connected to the SCR and configured to be turned on by an electro-static voltage, to trigger the SCR to be turned on; and
a first resistance, connected in parallel with at least part of the electro-static discharge path and configured to shunt a current of the electro-static discharge path when the SCR is turned on.

2. The ESD protection circuit of claim 1, further comprising:
a second resistance, connected between a gate of the NMOS transistor and the second potential terminal.

3. The ESD protection circuit of claim 1, wherein the SCR comprises a PNP-type transistor and an NPN-type transistor.

4. The ESD protection circuit of claim 3, wherein an emitter of the PNP-type transistor is connected to the first potential terminal;
a collector of the PNP-type transistor is connected to a base of the NPN-type transistor;
a base of the PNP-type transistor is connected to a collector of the NPN-type transistor; and
an emitter of the NPN-type transistor is connected to the second potential terminal.

5. The ESD protection circuit of claim 4, wherein the electro-static discharge path further comprises:
a first parasitic resistance, located between the emitter of the PNP-type transistor and the base of the PNP-type transistor.

6. The ESD protection circuit of claim 5, wherein the first parasitic resistance is configured to form an N-well in a semiconductor device in which the ESD protection circuit is formed.

7. The ESD protection circuit of claim 4, wherein the electro-static discharge path further comprises a second parasitic resistance located between the emitter of the NPN-type transistor and the base of the NPN-type transistor.

8. The ESD protection circuit of claim 7, wherein the second parasitic resistance is configured to form a P-well in a semiconductor device in which the ESD protection circuit is formed.

9. The ESD protection circuit of claim 7, wherein the first resistance is connected between the emitter of the NPN-type transistor and the base of the NPN-type transistor, and the first resistance is connected in parallel with the second parasitic resistance.

10. A semiconductor device, comprising:
a substrate; and
an N-well and a P-well that are in contact on the substrate and form a PN junction at a contact surface, wherein
the N-well comprises a first ion implantation region, and the first ion implantation region is connected to a first potential terminal;
the P-well comprises a second ion implantation region, and the second ion implantation region is connected to a second potential terminal;
the first ion implantation region and the second ion implantation region are configured to form an electro-static discharge path with the N-well and the P-well; and
the P-well is formed with a Negative channel-Metal-Oxide-Semiconductor (NMOS) transistor connected to the electro-static discharge path, and the NMOS transistor is configured to be turned on by an electro-static voltage, and to turn on the electro-static discharge path by the electro-static voltage; and
a first resistance, connected between the electro-static discharge path and the second potential terminal.

11. The semiconductor device of claim 10, further comprising:
a second resistance, connected between a gate of the NMOS transistor and the second potential terminal.

12. The semiconductor device of claim 10, wherein the first ion implantation region comprises a first N-type implantation region and a first P-type implantation region, and both the first N-type implantation region and the first P-type implantation region are connected to the first potential terminal.

13. The semiconductor device of claim 12, wherein
the second ion implantation region comprises a second N-type implantation region and a second P-type implantation region, and both the second N-type implantation region and the second P-type implantation region are connected to the second potential terminal;
the first P-type implantation region, the N-well, the first N-type implantation region and the second P-type implantation region are configured to form a PNP-type transistor of the electro-static discharge path; and
the first N-type implantation region, the N-well, the P-well and the second N-type implantation region are configured to form an NPN-type transistor of the electro-static discharge path.

14. The semiconductor device of claim 13, wherein the N-well comprises a first parasitic resistance, and the P-well comprises a second parasitic resistance.

15. The semiconductor device of claim 13, further comprising a third P-type implantation region located at an interface between the N-well and the P-well; wherein
the first resistance is connected between the third P-type implantation region and the second potential terminal.

16. The semiconductor device of claim 13, wherein an emitter of the PNP-type transistor is the first P-type implantation region and is connected to the first potential terminal, a collector of the PNP-type transistor is the second P-type implantation region and is connected to the second potential terminal through a resistance of the P-well.

17. The semiconductor device of claim 13, wherein a collector of the NPN-type transistor is the first N-type implantation region and is connected to the first potential terminal through a resistance of the N-well, an emitter of the NPN-type transistor is the second N-type implantation region and is connected to the second potential terminal, and a base of the NPN-type transistor is the second P-type implantation region and is connected to the second potential terminal through a resistance of the P-well.
